(19) United States
(12) Patent Application Publication
(10) Pub. No.: US 2007/0210369 A1
(43) Pub. Date: Sep. 13, 2007

(54) Single gate-non-volatile flash memory cell

(76) Inventors: Bomy Chen, Cupertino, CA (US); Yaw Wen Hu, Cupertino, CA (US); Dana Lee, Santa Clara, CA (US)

Correspondence Address: DLA PIPER RUDNICK GRAY CARY US, LLP, 2000 UNIVERSITY AVENUE, E. PALO ALTO, CA, 94303-2248, US

(21) Appl. No.: 11/375,386

(22) Filed: Mar. 13, 2006

(51) Int. Cl. H01L 29/788

(52) U.S. Cl. 257/315; 257/316

(57) ABSTRACT

A non-volatile floating gate memory cell, having a single polysilicon gate, compatible with conventional logic processes, comprises a substrate of a first conductivity type. A first and a second region of a second conductivity type are in the substrate, spaced apart from one another to define a channel region therebetween. A first gate is insulated from the substrate and is positioned over a first portion of the channel region and over the first region and is substantially capacitively coupled thereto. A second gate is insulated from the substrate, and is spaced apart from the first gate and is positioned over a second portion of the channel region, different from the first portion, and has little or no overlap with the second region.

### TECHNICAL FIELD

The present invention relates to a non-volatile floating gate memory cell using a single gate, and more particularly wherein the process to make the floating gate memory cell is compatible with conventional CMOS processes.

### BACKGROUND OF THE INVENTION

Single poly electrically programmable read only memory (EPROM) cells using a floating gate for storage of the electrons to program the cell is well known in the art. See, for example, U.S. Pat. No. 6,678,190. The advantage of a single polysilicon gate EPROM device is that a single polysilicon gate is compatible with conventional CMOS process. Thus, in, e.g., embedded applications, the process does not have to changed to manufacture the logic portion of the embedded device as well as the non-volatile floating gate memory portion of the device.

Referring to FIG. 1 there is shown a cross-sectional view of a single gate EPROM device 10 of the prior art, as shown in U.S. Pat. No. 6,678,190. The single gate EPROM floating gate memory cell 10 is made from a N type substrate 12 or N well 12. A first region 14 a second region 16 and a third region 18 each of the P+type is in the N well or N type substrate 12. Each of the first region 14, second region 16 and third region 18 is spaced apart from one another to define a first channel region 24 between the first region 14 and the second region 16 and a second channel region 26 between the second region 16 and the third region 18. Positioned over the first channel region 24 is a first polysilicon gate 20 spaced apart and insulated from the first channel region 24. The first gate 20 covers the first channel region 24 but has little or no overlap with the first region 14 and the second region 16. A second polysilicon gate 22, the floating gate 22, is spaced apart and insulated from the second channel region 26. The second polysilicon gate 22 also extends over the second channel region 26 but has little or no overlap with the second region 16 or third region 18. The first gate 20 and the second gate 20 are made in the same processing step and thus the device 10 is made of a single polysilicon gate.

In the operation of the device 10, a positive voltage such as +5 volts is applied to the first region 14. A lower voltage such as ground is applied to the third region 18. A low voltage such as ground is applied to the first gate 20. Since the first region 14, second region 16 and the first channel region 24 forms in essence a P type transistor, the application of 0 volts to the first gate 20 will turn on the first channel region 24. The voltage of +5 volts from the first region 14 is then passed through the first channel region 24 to the second region 16. At the second region 16, the holes are injected onto the second gate 22 by the mechanism of channel hot carrier.

Finally, to erase, the stored state on the floating gate 22 is altered by exposing the device 10 to ultraviolet rays. This is one of the problems of the device 10. Because the device 10 must be subject to UV or ultraviolet rays, single bits or bytes or blocks of an array of the EPROM device 10 cannot be erased apart from one another and the entire EPROM memory array must be erased. Further, erasure cannot be made in situ. Finally, the EPROM memory device 10 is made out of an N type substrate 12 or an N well 12. Such a device requires an extra implant step to a conventional CMOS process. See also U.S. Pat. Nos. 6,191,980 and 6,044,018 which were referenced in the background of the invention described in U.S. Pat. No. 6,678,190.

Accordingly, there is a need for a single poly floating gate memory device having in situ erase capability which is compatible with the conventional CMOS process.

Finally, the mechanism of hot channel injection in which a floating gate is substantially capacitively coupled to the source or drain region is disclosed in U.S. Pat. No. 5,029,130, whose disclosure is incorporated herein in its entirety by reference.

### SUMMARY OF THE INVENTION

Accordingly, in the present invention, a non-volatile floating gate memory cell comprises a substrate of a first conductivity type. A first and a second region of a second conductivity type are in the substrate, spaced apart from one another to define a channel region therebetween. A first gate is insulated from the substrate and is positioned over a first portion of the channel region and over the first region and is substantially capacitively coupled thereto. A second gate is insulated from the substrate and is spaced apart from the first gate and is positioned over a second portion of the channel region, different from the first portion, and having little or no overlap with the second region.

### BRIEF DESCRIPTION OF THE DRAWINGS

FIG. 1 is a cross-sectional view of a floating gate memory cell of the prior art, showing the mechanism of program.

FIG. 2 is a cross-sectional view of a first embodiment of a floating gate memory cell of the present invention, showing the mechanism of program.

FIG. 3 is a cross-sectional view of a second embodiment of a floating gate memory cell of the present invention, showing the mechanism of program.

FIG. 4 is a cross-sectional view of a third embodiment of a floating gate memory cell of the present invention, showing the mechanism of program.

FIG. 5 is a cross sectional view taken in a plane perpendicular to the cross sectional view shown in FIGS. 2-4, showing a portion of a fourth embodiment of a floating gate memory cell to be used with the first, second and third embodiments, showing the mechanism of erase.

FIG. 6 is a cross sectional view taken in a plane perpendicular to the cross sectional view shown in FIGS. 2-4, showing a portion of a fifth embodiment of a floating gate memory cell to be used with the first, second and third embodiments, showing the mechanism of erase.

FIG. 7 is a cross sectional view taken in a plane parallel to the cross sectional view shown in FIG. 2-4 showing a portion of a sixth embodiment of a floating gate memory cell to be used with the first, second and third embodiments, showing the mechanism of erase.

### DETAILED DESCRIPTION OF THE INVENTION

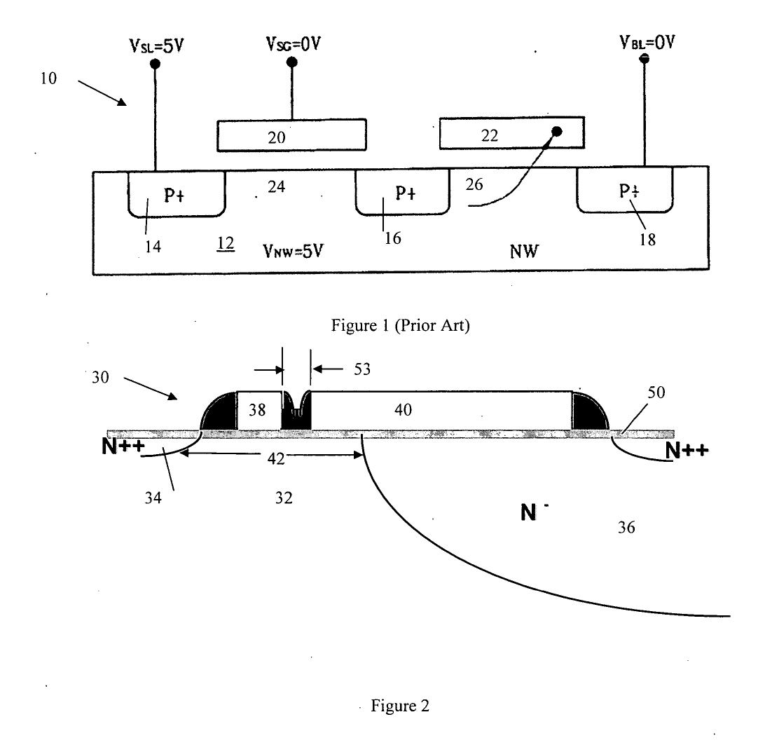

Referring to FIG. 2 there is shown a cross-sectional view of a first embodiment of a single poly floating gate memory cell 30 of the present invention. The cell 30 is formed in a P type substrate 32. A first region 34 of an N++ type is formed in the substrate 32. A second region 36 of an N++ type with a deep N-well 36 is formed in the substrate 32, spaced apart from the first region 34. A continuous channel region 42 is defined between the first region 34 and the second region 36. A first gate 38, preferably made of polysilicon, is positioned over a portion of the channel region 42. A second gate 40, the floating gate (and also preferably made of polysilicon), spaced apart from the first gate 38, is positioned over another portion of the channel region 42 and is substantially capacitively coupled to the second region 36 by being positioned substantially over that region 36. Preferably, the first polysilicon gate 38 and the floating gate 40 are formed in the same processing step.

In operation, to program the device 30, a ground voltage or a low voltage such as +0.5 volts is applied to the first region 34. A high voltage such as +7 to +10 volts is applied to the second region 36. A positive voltage such as +2 volts is applied to first gate 38. This is sufficient to turn on a portion of the channel region 42 over which the first gate 38 is positioned. Electrons from the first region 34 are attracted to the high positive voltage at the second region 36. However, at the junction between the first gate 38 and the second gate 40, the electrons will experience an abrupt voltage increase at gap 53 because the second gate 40 is substantially capacitively coupled to the second region 36 and has an effective voltage of, e.g., +5 to +8 volts. Thus, electrons are accelerated through the insulator 50 which separates the first and second gates 38 and 40 respectively from the substrate 32. The electrons are injected onto the second gate 40 which acts as a floating gate.

To erase the cell 30, one could subject the device 30 to ultraviolet ray exposure. However, as will also be seen hereinafter, the device 30 may be erased in situ electrically.

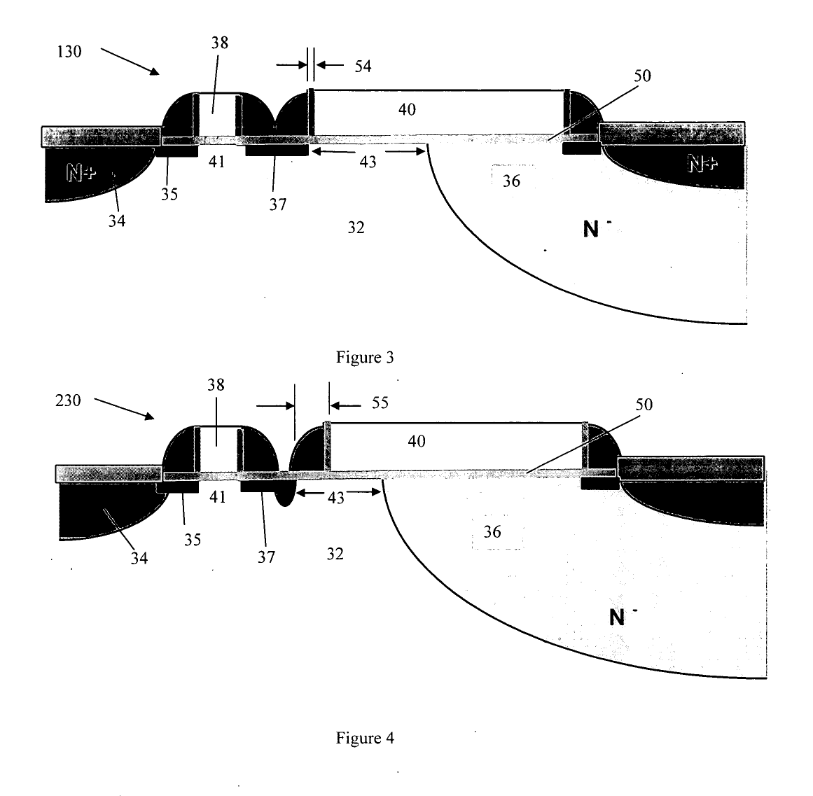

Referring to FIG. 3, there is shown a cross-sectional view of a second embodiment of the memory cell 130 of the present invention. Similar to the memory cell 30 shown in FIG. 2, the memory cell 130 is made from P type substrate 32. Within the substrate 32 are first region 34, of a N+ type material, a second region 36 of N+ material along with its N-well, and a third region 37 of a N+ material between the first region 34 and the second region 36. The third region 37 is spaced apart from the first region 34 and the second region 36 and serves to define two channel regions: a first channel region 41 between the third region 37 and the first region 34, and a second channel region 43 between the third region 37 and the second region 36. In addition, an LDD (lightly dope drain) extension 35 extends from the first region 34 and forms an integral part thereof.

A first gate 38 is positioned over the entirety of the first channel region 41 and is between the first region 34 along with its LDD 35 and the third region 37. A second polysilicon gate 40 which is the floating gate 40, is positioned substantially over the entirety of the second channel region 43 between the third region 37 and the second region 36. In addition, the second gate 40 extends substantially over the second region 36 and thus is substantially capacitively coupled thereto.

The operation of the device 130 is very similar to the operation of the device 30. A low voltage or ground voltage is applied to the first region 34 while a high positive voltage is applied to the second region 36. A positive voltage is applied to the first gate 38 thereby turning on the first channel region 41. Electrons migrate from the first region 34 through the LDD 35 through the channel region 41 to the third region 37. Because the second gate 40 is substantially capacitively coupled to the second region 36, the second gate 40 would experience a high voltage. The electrons at the third region 37 would then experience via a small gap 54 a high voltage potential from the second gate 40 and would be injected to the second gate 40 through the insulating region 50, thereby programming the floating gate 40.

Ease operation can occur by UV erase or as disclosed hereinafter through electrical operation.

Referring to FIG. 4 there is shown a cross-sectional view of a third embodiment of a memory cell 230 of the present invention. The memory cell 230 is similar to the memory cell 130 shown in FIG. 3. The only difference between the memory cell 230 and the memory cell 130 is that the second gate 40 is not positioned over the entirety of the second channel region 43. Instead, it is positioned over only a portion of the second channel 43. In all other respects, the memory cell 230 is the same as the memory cell 130. Thus, the memory cell 230 comprises a P type substrate 32. Within the substrate 32 are first region 34, of a N+ type material, a second region 36 of N+ material along with its N-well, and a third region 37 of a N+ material between the first region 34 and the second region 36. The third region 37 is spaced apart from the first region 34 and the second region 36 and serves to define two channel regions: a first channel region 41 between the third region 37 and the first region 34, and a second channel region 43 between the third region 37 and the second region 36. In addition, an LDD (lightly dope drain) extension 35 extends from the first region 34 and forms an integral part thereof.

A first gate 38 is positioned over the entirety of the first channel region 41 and is between the first region 34 along with its LDD 35 and the third region 37. A second polysilicon gate 40 which is the floating gate 40, is positioned over a portion of the second channel region 43 between the third region 37 and the second region 36. In addition, the second gate 40 extends substantially over the second region 36 and thus is substantially capacitively coupled thereto.

In the operation of the memory cell 230, to program the memory cell 230, the programming operation is again similar to the programming operation for the memory cell 130. To program the memory cell 230 a low voltage or ground voltage is applied to the first region 34 while a high positive voltage is applied to the second region 36. A positive voltage is applied to the first gate 38 thereby turning on the first channel region 41. Electrons migrate from the first region 34 through the LDD 35 through the channel region 41 to the third region 37. Because the second gate 40 is substantially capacitively coupled to the second region 36, the second gate 40 would experience a high voltage. The electrons at the third region 37 are attracted to the high positive potential at the second region 36 and begin to traverse the channel region 43 through the gap 55. However, they also experience a high voltage potential from the second gate 40 and would be injected to the second gate 40 through the insulating region 50, thereby programming the floating gate 40.

Finally, ease operation can occur by UV erase or as disclosed hereinafter through electrical operation.

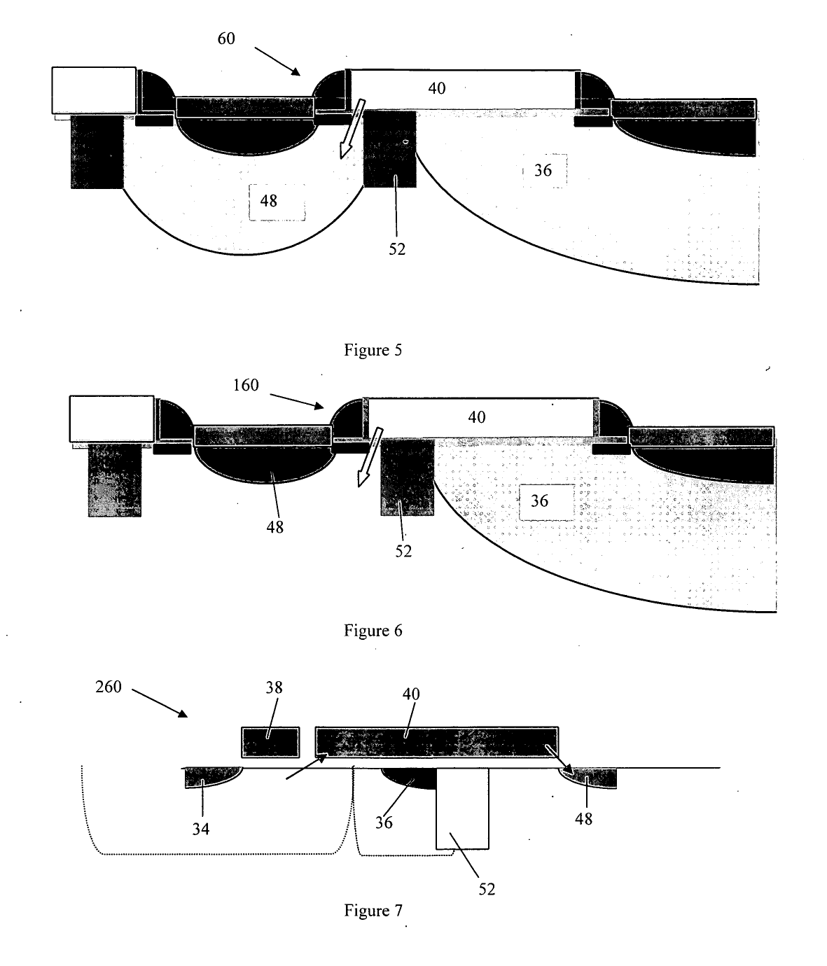

Referring to FIG. 5 there is shown a structure 60 to be used with either the cell 30, 130, or 230 to erase the floating gate 40. The view shown in FIG. 5 is a cross-sectional view taken in a direction orthogonal or perpendicular to the views taken in FIGS. 2-4. Thus, the structure 60 forms an L shaped structure with the structure 30, 130, or 230. The erase portion shown in FIG. 5 consists of the continuation of the polysilicon gate 40 and the second region 36. A fourth region 48 comprising an N type conductivity well is spaced apart from the second region 36. Between the fourth region 48 and the second region 36 is an insulation region 52 such as an STI (shallow trench isolation) 52. The floating gate 40 is positioned over the entire channel region between the second region 36 and the fourth region 48.

To erase the floating gate 40, a high positive voltage such as 7-9.5 volts is applied to the fourth region contact 48. A low voltage such as ground or as zero volts is applied to the second region 36. Since the second region 36 is highly capacitively coupled to the floating gate 40, the floating gate 40 also experiences a substantially zero volts thereon. Electrons on the floating gate 40 are attracted to the high positive voltage in the well 48 and through the mechanism of Fowler-Nordheim, tunnel from the floating gate 40 through the insulator 50 into the well 48. The STI 52 or the insulation region 52 is maintained so as to prevent any carriers from migrating in the channel region between the second region 36 and the fourth region 48 during the erase operation.

Referring to FIG. 6 there is shown a cross-sectional view of another structure 160 which can be used with the cell 30, 130 and 230 shown in FIGS. 2-4 to cause erasure of the floating gate 40 shown in those cells. The structure 160 is similar to the structure 60 shown in FIG. 5. Thus, the view shown in FIG. 6 is in a cross-sectional view in a plane which is perpendicular to the plane shown in FIGS. 2-4, with the structure 60 forming an L shaped structure with the cells 30, 130, or 230. The erase portion shown in FIG. 6 consists of the continuation of the polysilicon gate 40 and the second region 36. A fourth region 48 comprising an N type conductivity well is spaced apart from the second region 36. Between the fourth region 48 and the second region 36 is an insulation region 52 such as an STI (shallow trench isolation) 52. The floating gate 40 is positioned over the entire channel region between the second region 36 and the fourth region 48. However, in contrast to the structure 60 shown in FIG. 5, the structure 160 has a shallow fourth region 48. Thus, the STI 52 does not cover the entire region between the fourth region 48 and the second region 36. The floating gate 40 is positioned over the channel region between the fourth region 48 and the second region 36. In operation, again, similar to the structure 60, a ground voltage or zero volt is applied to the second region 36. Since the floating gate 40 is strongly capacitively coupled to the second region 36 it also experiences a substantially zero or ground voltage. The positive high voltage placed on the fourth region 48 causes the region 48 to create a junction which expands beyond the physical region 48. This junction expands underneath the floating gate 40 and through the Fowler-Nordheim mechanism, electrons from the floating gate 40 tunnel to the junction underneath the fourth region 48. Therefore, the only difference between the structure 60 and the structure 160 is that in the structure 60, electrons from the floating gate 40 tunnel directly to a N well region 48, whereas in the structure 160, electrons from the floating gate 40 tunnel into a junction created by the application of a voltage on the region 48.

Referring to FIG. 7 there is shown a cross-sectional view of a structure 260 to accomplish erase. This structure 260 can be used with the cell structure 30, 130 or 230 shown in FIGS. 2-4. The view shown in FIG. 7 is in a cross-sectional view which is parallel to the views shown in FIGS. 2-4. In the structure shown in FIG. 7, the floating gate 40 extends over the entirety of the second region 36 and beyond. A fourth region 48 of the second connectivity type is co-linear with the first region 34 and the second region 36. Thus, the entire structure 260 is linearly shaped. Similar to the discussion for the structure 60 and 160, an STI region 52 is in the channel region between the second region 36 and the fourth region 48. During erase, the second region 36 is connected to a source of ground or low voltage. This is highly capacitively coupled to the floating gate 40. A positive high voltage is applied to the fourth region 48. Through the mechanism of Fowler-Nordheim tunnel, either the electrons from the floating gate 40 are tunneled through the insulator 50 to the well 48 underneath the fourth region 48 or through the junction created by the positive voltage applied to the fourth region 48, similar to the operations described heretofore for the devices 60 and 160, respectively.

From the foregoing, it can be seen that a novel single gate floating gate memory cell, compatible with convention of CMOS process, is disclosed. The single gate OTP (one time programmable) device, can be a one time programmable device or through the addition of an erase structure can be a many time programmable device.

What is claimed is:

1. A non-volatile floating gate memory cell comprising:
a substrate of a first conductivity type;
a first and a second region of a second conductivity type in said substrate, spaced apart from one another defining a channel region therebetween;
a first gate insulated from said substrate and positioned over a first portion of the channel region and over the first region and being substantially capacitively coupled thereto; and
a second gate insulated from said substrate, spaced apart from the first gate and positioned over a second portion of the channel region, different from the first portion, and having little or no overlap with the second region.

2. The memory cell of claim 1 wherein said first gate and said second gate are formed in the same step.

3. The memory cell of claim 2 wherein said channel region is a continuous channel region.

4. The memory cell of claim 3 wherein said first conductivity is P type.

5. The memory cell of claim 4 wherein said first and second gates are formed of polysilicon.

6. The memory cell of claim 2 further comprising:
a third region of the second conductivity type between said first region and said second region, spaced apart therefrom to define a second channel region between the third region and the first region, and to define a third channel region between the third region and the second region;
wherein the first gate is positioned over a portion of the second channel region and is substantially capacitively coupled to the first region; and
wherein said second gate is positioned over the third channel region and has little or no overlap with the second region.

7. The memory cell of claim 6 wherein the second and third channel regions are substantially co-linear.

8. The memory cell of claim 6 further comprising
a fourth region of the second conductivity type in said substrate, spaced apart from said first, second and third regions, with a fourth channel region between said fourth region and said first region;
an insulating region between said first region and said fourth region in said fourth channel region.

9. The memory cell of claim 8 wherein said insulating region is immediately adjacent to and contiguous with said first region.

10. The memory cell of claim 2 further comprising:
a third region of the second conductivity type in said substrate spaced apart from said first region to define a second channel region between said first region and said third region;
an insulator in said second channel region between said first region and said third region.
